(19) United States
(12) Patent Application Publication
(10) Pub. No.: US 2009/0134431 A1
(43) Pub. Date: May 28, 2009

(54) NONVOLATILE SEMICONDUCTOR STORAGE APPARATUS AND METHOD OF MANUFACTURING THE SAME

(75) Inventors: Hideyuki TABATA, Kawasaki-shi (JP); Hiroyuki NAGASHIMA, Yokohama-shi (JP); Hirofumi INOUE, Kamakura-shi (JP); Kohichi KUBO, Yokohama-shi (JP); Masanori KOMURA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/275,794

(22) Filed: Nov. 21, 2008

(30) Foreign Application Priority Data
Nov. 22, 2007 (JP) 2007-303663

(51) Int. Cl. H01L 29/66; H01L 29/00; H01L 21/20

(52) U.S. Cl. 257/210; 257/208; 257/536; 438/382; 257/E29.166; 257/E29.001

(57) ABSTRACT

A nonvolatile semiconductor storage apparatus includes: a plurality of first wirings; a plurality of second wirings which cross the plurality of first wirings; and a memory cell which is connected between both the wirings at an intersection of the first and second wirings, and includes a variable resistive element operative to store information according to a change in resistance and includes a variable resistive element, wherein the memory cell is formed so that a cross section area of the variable resistive element becomes smaller than a cross section area of the other portion.

### CROSS-REFERENCE TO RELATED APPLICATIONS

This application is based upon and claims the benefit of priority from the prior Japanese Patent Application No. 2007-303663, filed on Nov. 22, 2007, the entire contents of which are incorporated herein by reference.

### BACKGROUND OF THE INVENTION

1. Field of the Invention

The present invention relates to a nonvolatile semiconductor apparatus using a variable resistive element and a method of manufacturing the same.

2. Description of the Related Art

Conventionally, as nonvolatile memories which enable rewriting electrically, flash memories, in which memory cells having a floating gate structure are NAND-connected or NOR-connected so that a memory cell array is structured, are publicly known. As nonvolatile memories which enable high-speed random access, ferroelectric memories are also known.

On the other hand, as a technique for improving further miniaturization of memory cells, resistance-change type memories in which variable resistive elements are used as memory cells are proposed. As the variable resistive elements, phase-change memory elements in which resistance is changed by a state transition, namely, crystallization/amorphousness of chalcogenide compounds, MRAM elements using resistance change caused by a tunnel magnetoresistance effect, memory elements of polymer ferroelectric RAM (PFRAM) in which resistive elements are formed by conductive polymer, and ReRAM elements in which resistance changes due to application of an electric pulse are known (Patent Document 1: Japanese Patent Application Laid-Open No. 2006-344349, paragraph 0021).

In the resistance-change memory, memory cells can be structured by a series circuit of a schottky diode and a resistance-change element instead of a transistor. For this reason, this memory has advantages in that lamination is easy and higher integration can be realized by a three-dimensional structure (Patent Document 2: Japanese Patent Application Laid-Open No. 2005-522045).

In the conventional resistance-change memory, resistance of a variable resistive element is set to an initial value by an energy given from the outside, but when a sufficient current density is not given, the resetting takes a long time or the resistance is not reset. When heat generation from a non-ohmic element to be connected to the variable resistive element in series increases, a leak current at the time of reverse bias increases, and consumption current in all the memory cells increases.

### SUMMARY OF THE INVENTION

A nonvolatile semiconductor storage apparatus according to one aspect of the invention includes: a plurality of first wirings; a plurality of second wirings which cross the plurality of first wirings; and a memory cell which is connected between both the wirings at an intersection of the first and second wirings, and includes a variable resistive element operative to store information according to a change in resistance, wherein the memory cell is formed so that a cross section area of the variable resistive element becomes smaller than a cross section area of the other portion.

A nonvolatile semiconductor storage apparatus according to another aspect of the invention comprising: a memory cell array including plural stacked cell array layers, each cell array layer comprising a plurality of first wirings, a plurality of second wirings which cross the plurality of first wirings, and memory cells which are connected at intersections of the first and second wirings, and each memory cell includes a variable resistive element operative to store information according to a change in resistance, wherein the memory cell is formed so that a cross section area of the variable resistive element becomes smaller than a cross section area of the other portion.

A method of manufacturing a nonvolatile semiconductor storage apparatus according to another aspect of the invention includes: forming, on a semiconductor substrate, a laminated body in which at least an interlayer insulating film, a layer for forming a first wiring, a layer for forming a non-ohmic element and a layer for forming a variable resistive element are sequentially laminated; forming a plurality of first grooves on the laminated body, the first grooves extending in a direction where the first wirings are formed, their opening side being wider than their bottom surface side, their depth reaching a lower surface of the layer for forming the first wirings, embedding a first insulating film into the first grooves; forming a plurality of second grooves on the laminated body into which the first insulating film is embedded, the second grooves extending in a direction where the second wirings crossing the first wirings are formed, their opening side being wider than their bottom surface side, their depth reaching an upper surface of the layer for forming the first wirings; embedding a second insulating film into the second grooves; and forming the second wirings on the laminated body into which the second insulating film is embedded.

### BRIEF DESCRIPTION OF THE DRAWINGS

FIG. 1 is a block diagram illustrating a nonvolatile memory according to a first embodiment of the present invention;

FIG. 2 is a perspective view illustrating a part of a memory cell array of the nonvolatile memory according to the first embodiment;

FIG. 3 is an enlarged perspective view illustrating one memory cell in FIG. 2;

FIG. 4 is a schematic cross-sectional view illustrating one example of a variable resistive element according to the first embodiment;

FIG. 5 is a schematic cross-sectional view illustrating another example of the variable resistive element according to the first embodiment;

FIG. 6 is schematic cross-sectional views illustrating examples of a non-ohmic element according to the first embodiment;

FIG. 7 is a circuit diagram illustrating the memory cell array and a peripheral circuit thereof according to another embodiment of the present invention;

FIG. 8 is a cross-sectional view illustrating the nonvolatile memory according to the embodiment;

FIG. 9 is a perspective view illustrating steps of forming an upper layer portion of the nonvolatile memory in order of the steps according to the embodiment;

FIG. 10 is a perspective view illustrating steps of forming the upper layer portion of the nonvolatile memory in order of the steps according to the embodiment;

FIG. 11 is a perspective view illustrating steps of forming the upper layer portion of the nonvolatile memory in order of the steps according to the embodiment;

FIG. 12 is a perspective view illustrating steps of forming the upper layer portion of the nonvolatile memory in order of the steps according to the embodiment;

FIG. 13 is a perspective view illustrating steps of forming the upper layer portion of the nonvolatile memory in order of the steps according to the embodiment;

FIG. 14 is a perspective view illustrating steps of forming the upper layer portion of the nonvolatile memory in order of the steps according to the embodiment;

FIG. 15 is a perspective view illustrating steps of forming the upper layer portion of the nonvolatile memory in order of the steps according to the embodiment;

FIG. 16 is a perspective view illustrating steps of forming the upper layer portion of the nonvolatile memory in order of the steps according to the embodiment;

FIG. 17 is a perspective view illustrating steps of forming the upper layer portion of the nonvolatile memory in order of the steps according to the embodiment;

FIG. 18 is a perspective view illustrating steps of forming the upper layer portion of the nonvolatile memory in order of the steps according to the embodiment;

FIG. 19 is an enlarged perspective view illustrating the memory cell of the nonvolatile memory according to a second embodiment of the present invention;

FIG. 20 is an enlarged perspective view illustrating the memory cell of the nonvolatile memory according to a third embodiment of the present invention;

FIG. 21 is a perspective view illustrating the memory cell of the nonvolatile memory according to still another embodiment of the present invention; and

FIG. 22 is a cross-sectional view illustrating the memory cell of the nonvolatile memory according to the embodiment.

### DETAILED DESCRIPTION OF THE EMBODIMENTS

Embodiments of the present invention will be described below with reference to the drawings.

### First Embodiment

[Entire Constitution]

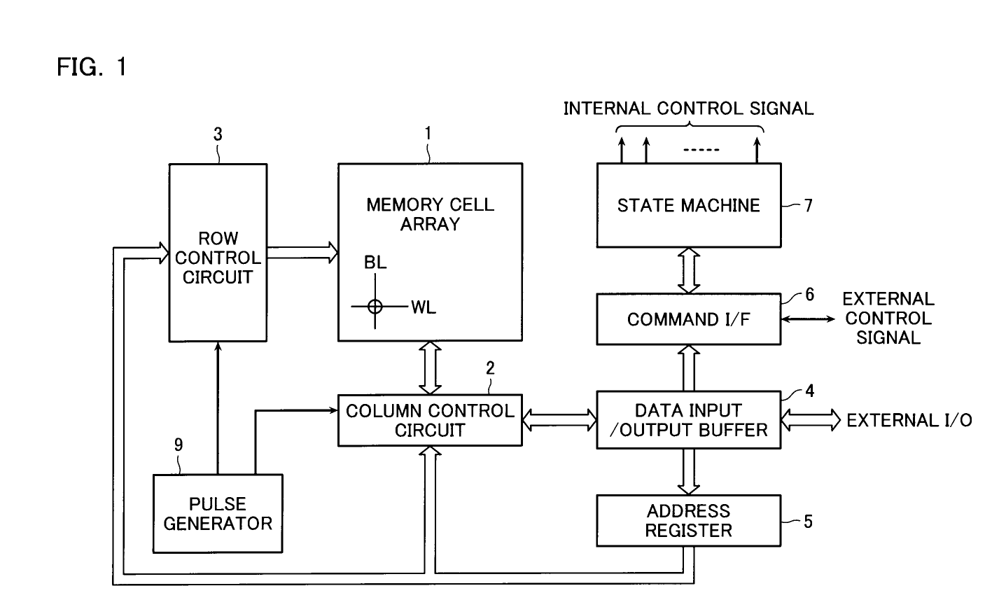

FIG. 1 illustrates a block diagram illustrating a nonvolatile memory according to a first embodiment of the present invention.

The nonvolatile memory includes a memory cell array 1 in which memory cells using ReRAM (variable resistive elements), described later, are arranged into a matrix pattern. A column control circuit 2 is provided on a position adjacent to the memory cell array 1 in a bit line BL direction. The column control circuit 2 controls the bit line BL of the memory cell array 1, erases data in the memory cells, writes data into the memory cells and reads data from the memory cells. A row control circuit 3 is provided on a position adjacent to the memory cell array 1 in a word line WL direction. The row control circuit 3 selects the word line WL of the memory cell array 1, and applies voltages necessary for erasing data in the memory cells, writing data into the memory cells and reading data from the memory cells.

A data input/output buffer 4 is connected to an external host, not shown, via an I/O line, receives writing data and an erase command, outputs reading data, and receives address data and command data. The data input/output buffer 4 transmits the received writing data to the column control circuit 2, and receives the data read from the column control circuit 2 so as to output the read data to the outside. An address supplied from the outside to the data input/output buffer 4 is sent to the column control circuit 2 and the row control circuit 3 via an address register 5. A command supplied from the host to the input/output buffer 4 is sent to a command interface 6. The command interface 6 receives an external control signal from the host, determines whether the data input into the data input/output buffer 4 is writing data, a command or an address. When the input data is the command, the command interface 6 transmits it as a reception command signal to a state machine 7. The state machine 7 manages the entire nonvolatile memory, accepts a command from the host, and manages reading, writing, erasing and input/output of data. The external host receives status information managed by the state machine 7 so as to be capable of determining an operation result. The status information is used for controlling the writing and erasing.

The state machine 7 controls a pulse generator 9. This control enables the pulse generator 9 to output a pulse of any voltage at any timing. The generated pulse can be transmitted to any wirings selected by the column control circuit 2 and the row control circuit 3.

A peripheral circuit element other than the memory cell array 1 can be formed on an Si substrate just below the memory cell array 1 formed on a wiring layer. As a result, a chip area of the nonvolatile memory can be made approximately equal to an area of the memory cell array 1.

[Memory Cell Array and its Peripheral Circuit]

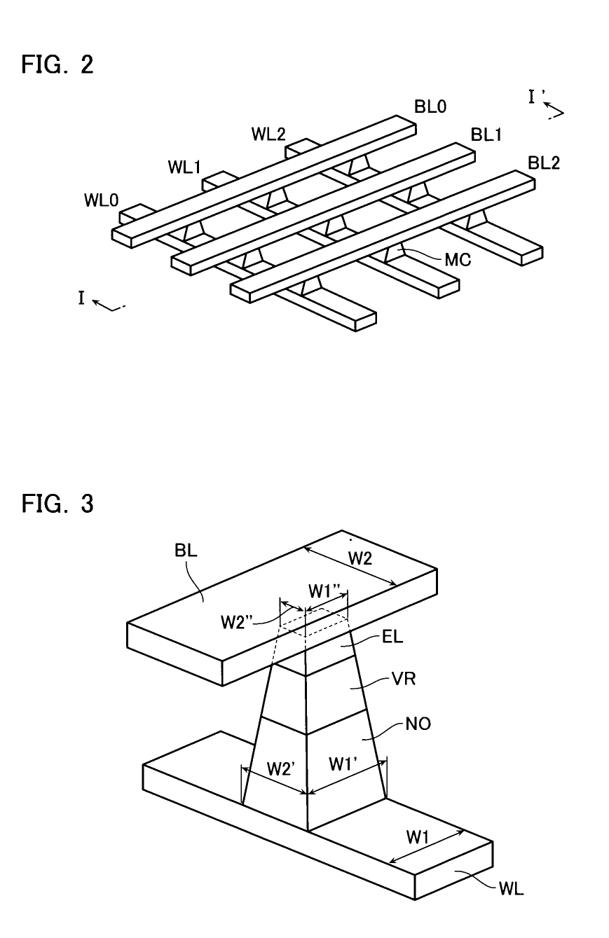

FIG. 2 is a perspective view illustrating a part of the memory cell array 1, and FIG. 3 is an enlarged perspective view illustrating one memory cell in FIG. 2.

Word lines WL0 to WL2 are disposed in parallel as a plurality of first wirings, and bit lines BL0 to BL2 are disposed as a plurality of second wirings so as to cross the word lines WL0 to WL2. A memory cell MC is arranged on their intersection so as to be sandwiched by both the wirings. A material of the first and second wirings is desirably resistant to heat and has low resistance, and for example, W, WSi, NiSi, CoSi or the like can be used.

The memory cell MC is composed of a circuit where a variable resistive element VR and a non-ohmic element NO are connected in series as shown in FIG. 3.

The variable resistive element VR can change resistance according to application of a voltage via electric current, heat, or chemical energy. An electrode EL which functions as a barrier metal and an adhesive layer may be arranged on and under the variable resistive element VR. When the electrode is arranged, Pt, Au, Ag, TiAlN, SrRuO, Ru, RuN, Ir, Co, Ti, TiN, TaN, LaNiO, Al, PtIrOx, PtRhOx, Rh/TaAlN or the like is used as an electrode material. A metal film which makes orientation uniform can be inserted. Additionally, a buffer layer, a barrier metal layer, an adhesive layer or the like can be inserted.

In the first embodiment, the non-ohmic element NO, the variable resistive element VR and the electrode EL are arranged in this order from the word line WL side to the bit line BL side, so that a pillar-shaped memory cell MC is formed. The memory cell MC is formed into a tapered shape in which its cross section is gradually reduced from the non-ohmic element NO side to the electrode EL side. That is, when a width of the word line WL arranged on the non-ohmic element NO side is denoted by W1, a width of the bit line BL arranged on the electrode EL side is denoted by W2, a width of the memory cell MC in a bit line BL direction at a connecting terminal on the word line WL side and a width thereof in a word line WL direction are denoted by W1′ and W2′, respectively, and a width of the memory cell MC in the bit line BL direction at the connecting terminal on the bit line BL side and a width thereof in the word line WL direction are denoted by W1″ and W2″, respectively, the following relationship holds:

W1=W1′>W1″

W2,W2′>W2″. [Mathematical formula I]

The variable resistive element VR is composed of a composite compound containing cations to be transition elements, and its resistance changes due to transfer of the cations (ReRAM).

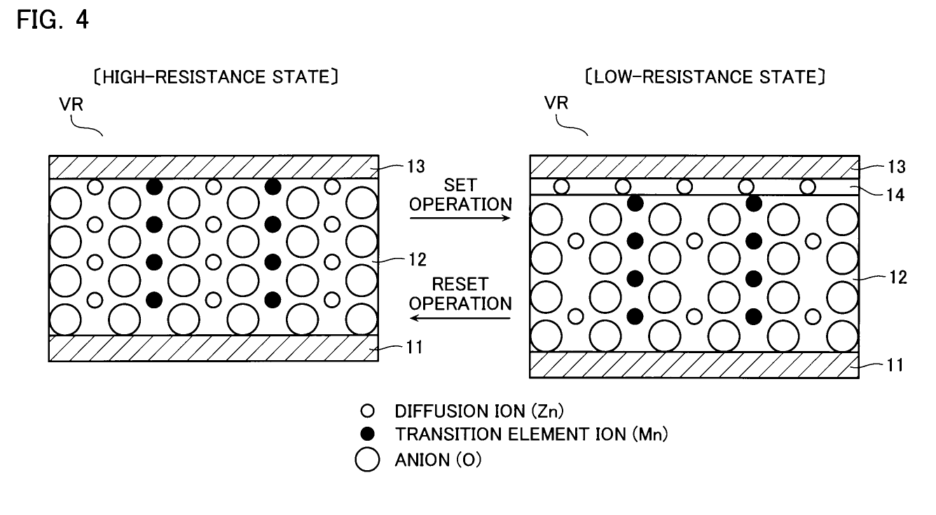

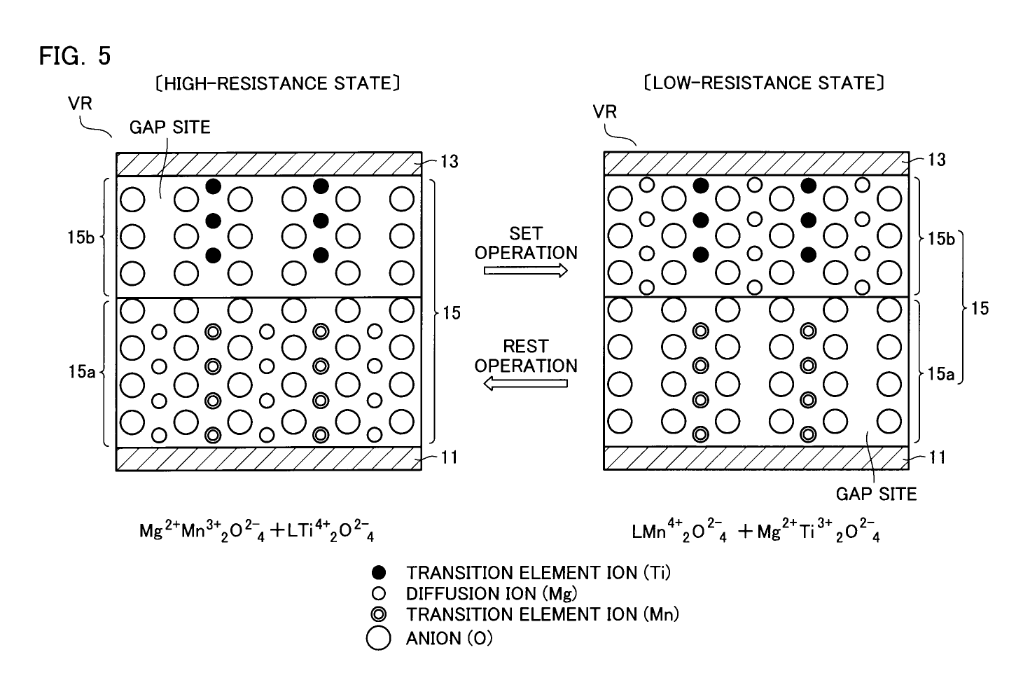

FIGS. 4 and 5 are diagrams illustrating examples of the variable resistive element. The variable resistive element VR shown in FIG. 4 is constituted by arranging a recording layer 12 between electrode layers 11 and 13. The recording layer 12 is composed of a composite compound having at least two kinds of cationic elements. At least one of the cationic elements is a transition element having a d orbital in which an electron is insufficiently filled, and the shortest distance between the adjacent cationic elements is not more than 0.32 nm. Specifically, the recording layer 12 is expressed by a chemical formula AₓM_{y}X_{z} (A and M are different elements), and is composed of a material having a crystal structure such as a spinel structure (AM₂O₄), an ilmenite structure (AMO₃), a delafossite structure (AMO₂), an LiMoN₂ structure (AMN₂), a wolframite structure (AMO₄), an olivine structure (A₂MO₄), a hollandite structure (AₓMO₂), a ramsdelite structure (AₓMO₂) or a perovskite structure (AMO₃).

In the example of FIG. 4, A is Zn, M is Mn and X is O. A small white circle in the recording layer 12 shows a diffusion ion (Zn), a large white circle shows anion (O), and a small black circle shows transition element ion (Mn). An initial state of the recording layer 12 is a high-resistance state. When a fixed potential is applied to the electrode layer 11 and a negative voltage is applied to the electrode layer 13, some of diffusion ions in the recording layer 12 transfer to the electrode layer 13 side, and the diffusion ions in the recording layer 12 are reduced relatively with respect to the anions. The diffusion ions which transfer to the electrode layer 13 side receive electrons from the electrode layer 13 and metal is separated out so that a metal layer 14 is formed. Inside the recording layer 12, the anions are in excess, and as a result, valence of the transition element ions in the recording layer 12 increases. As a result, the recording layer 12 has electron conductivity due to injection of carriers, so that a set operation is completed. In the case of reproduction, it is only necessary to apply an electric current of minute value to an extent that the resistance of the material composing the recording layer 12 does not change. In order to reset a program state (low-resistance state) into the initial state (high-resistance state), a large electric current is applied to the recording layer 12 for sufficient time, and the recording layer 12 is Joule-heated so that oxidation-reduction reaction of the recording layer 12 may be accelerated. The reset operation is enabled also by applying an electric field of opposite direction to that at the time of the setting.

In the example of FIG. 5, a recording layer 15 sandwiched between the electrode layers 11 and 13 is formed by two layers including a first compound layer 15a and a second compound layer 15b. The first compound layer 15a is arranged on the electrode layer 11 side and is expressed by a chemical formula AₓM1_{y}X1_{z}. The second compound layer 15b is arranged on the electrode layer 13 side and has a gap site which can house the cation elements of the first compound layer 15a.

In the example of FIG. 5, A in the first compound layer 15a is Mg, M1 is Mn and X1 is O. The second compound layer 15b includes Ti shown by a black circle as the transition element ion. A small white circle in the first compound layer 15a shows a diffusion ion (Mg), a large white circle shows anion (O), and a double circle shows transition element ion (Mn). Two or more layers of the first compound layers 15a and the second compound layers 15b may be laminated.

In the variable resistive element VR, an electric potential is applied to the electrode layers 11 and 13 so that the first compound layer 15a becomes an anode side and the second compound layer 15b becomes a cathode side. When potential gradient is generated in the recording layer 15, some of the diffusion ions in the first compound layer 15a transfer in crystal, and enter the second compound layer 15b on the cathode side. Since the gap site which can house the diffusion ions is present in the crystal of the second compound layer 15b, the diffusion ions transferred from the first compound layer 15a side are housed in the gap site. For this reason, the valence of the transition element ions in the first compound layer 15a increases, and the valence of the transition element ions in the second compound layer 15b decreases. In the initial state, when the first and second compound layers 15a and 15b are in the high-resistance state, some of the diffusion ions in the first compound layer 15a transfer into the second compound layer 15b. As a result, conduction carriers are generated in the crystal of the first and second compounds, and both of them have electric conducting property. In order to reset the program state (low-resistance state) into an erase state (high-resistance state), similarly to the former example, a large electric current is applied to the recording layer 15 for sufficient time, and the recording layer 15 is Joule-heated so that the oxidation-reduction reaction of the recording layer 15 may be accelerated. The resetting is enabled also by applying an electric field of the opposite direction to that at the time of the setting.

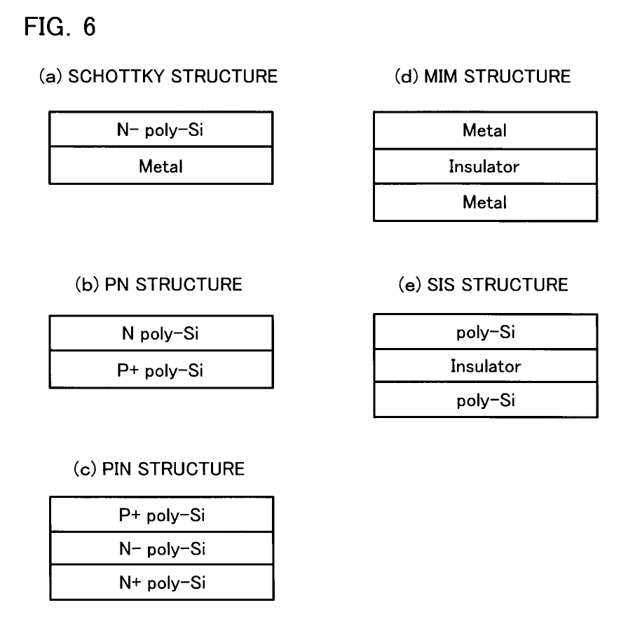

As shown in FIG. 6, for example, the non-ohmic element NO is composed of various diodes such as (a) a schottky diode, (b) a PN-junction diode and (c) a PIN diode, (d) MIM (Metal-Insulator-Metal) structure or (e) SIS structure (Silicon-Insulator-Silicon). Electrodes EL2 and EL3 forming a barrier metal layer and an adhesive layer may be inserted. When the diode is used, an unipolar operation can be performed due to its property, and in the case of the MIM structure or the SIS structure, a bipolar operation can be performed.

In the first embodiment, the memory cell MC is formed into the tapered shape so that its section area is gradually reduced from the non-ohmic element NO side to the variable resistive element VR side. For this reason, since the cross section area of the variable resistive element VR becomes small, the current density can be improved, and the Joule heat is efficiently generated so that a reset speed can be improved. As a result, the reset operation can be performed by a short pulse. Since the cross section area of the non-ohmic element can be enlarged, a sufficient electric current necessary for the reset can be applied. Overheat of the non-ohmic element is prevented, so that a leak current at the time of reverse bias can be suppressed.

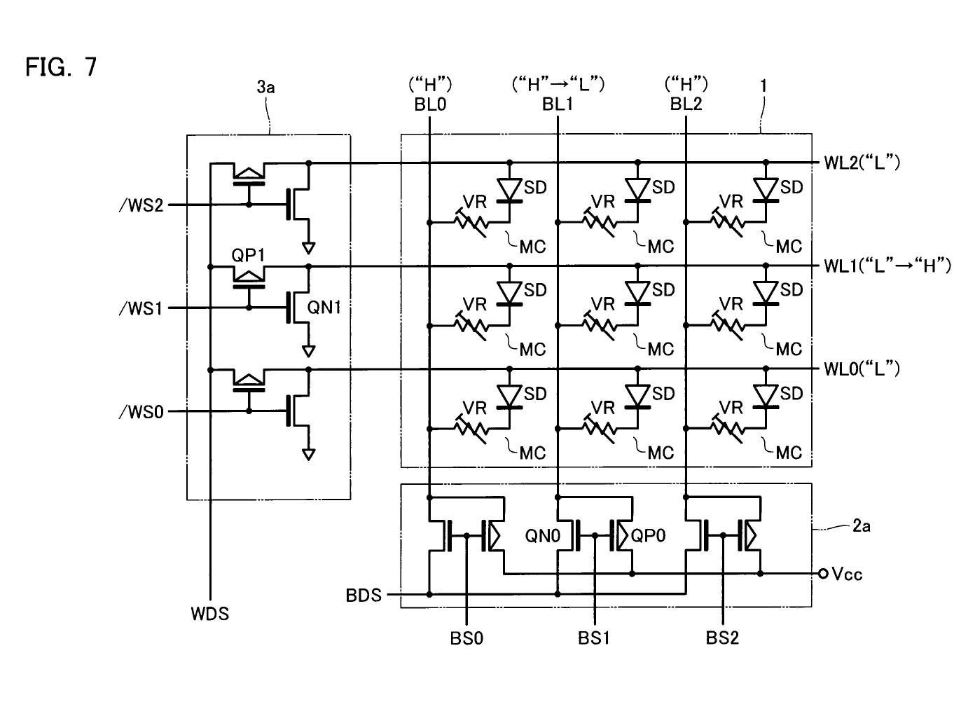

FIG. 7 is a circuit diagram illustrating the memory cell array 1 using a diode SD as the non-ohmic element NO and its peripheral circuit. For easy description, one-layered structure is described.

In FIG. 7, an anode of the diode composing the memory cell MC is connected to the word line WL, and a cathode is connected to the bit line BL via the variable resistive element VR. One end of each bit line BL is connected to a selection circuit 2a as a part of the column control circuit 2. One end of each word line WR is connected to a selection circuit 3a as a part of the row control circuit 3.

The selection circuit 2a is composed of a selection PMOS transistor QP0 and a selection NMOS transistor QN0 which are provided for each bit line BL and in which a gate and a drain are commonly connected. A source of the selection PMOS transistor QP0 is connected to a high-potential power source Vcc. A source of the selection NMOS transistor QN0 is connected to a drive sense line BDS on the bit line side to which a writing pulse and an electric current to be detected at the time of reading data are applied. A common drain of the transistors QP0 and QN0 is connected to the bit line BL, and a bit line selection signal BSi for selecting each bit line BL is supplied to a common gate.

The selection circuit 3a is composed of a selection PMOS transistor QP1 and a selection NMOS transistor QN1 which are provided for each word line WL and in which a gate and a drain are commonly connected. A source of the selection PMOS transistor QP1 is connected to a drive sense line WDS on the word line side to which a writing pulse and an electric current to be detected at the time of reading data are applied. A source of the selection NMOS transistor QN1 is connected to a low-potential power source Vss. The common drain of the transistors QP1 and QN1 is connected to the word line WL, and a word line selection signal /WSi for selecting each word line WL is supplied to the common gate.

The above-described example is suitable for selecting the memory cells individually. When data in the plurality of memory cells MC connected to the selected word line WL is collectively read, a sense amplifier is arranged for each of the bit lines BL0 to BL2. The bit lines BL0 to BL2 are connected to the sense amplifiers, respectively, via the selection circuit 2a by the bit line selection signal BS.

In the memory cell array 1, polarity of the diode SD is made to be opposite to that of the circuit shown in FIG. 7 so that an electric current may be applied from the bit line BL side to the word line WL side.

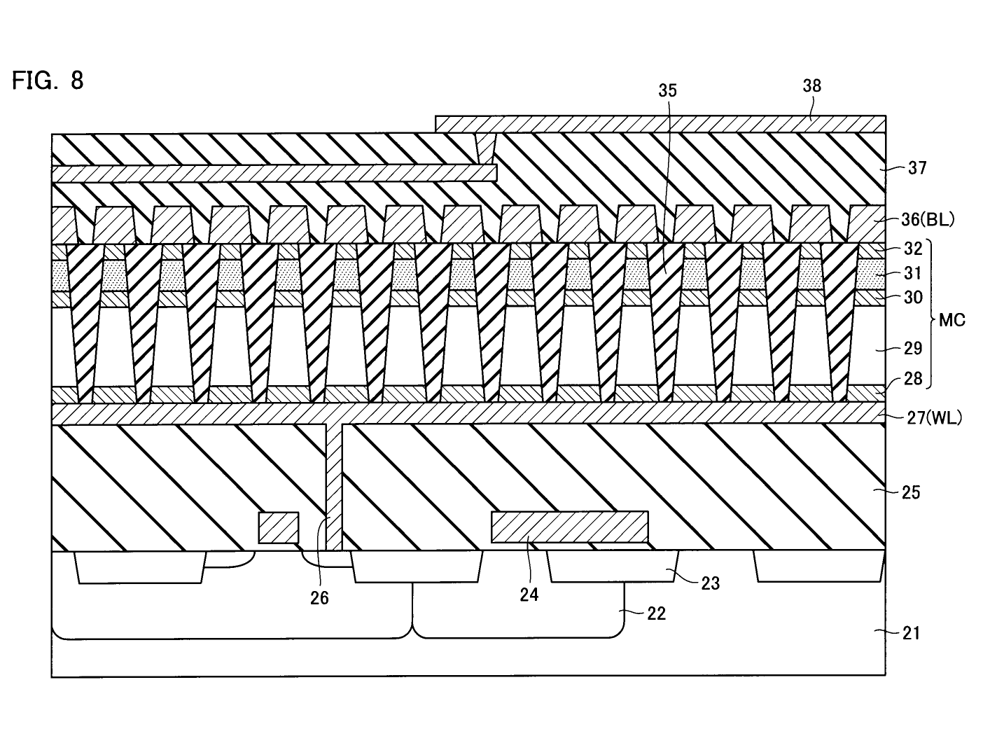

FIG. 8 is a cross-sectional view illustrating the nonvolatile memory including one stage of the memory structure. An impurity diffusion layer 23 and a gate electrode 24 of the transistor composing the peripheral circuit are formed on a silicon substrate 21 formed with a well 22. A first interlayer insulating film 25 is deposited thereon. A via 26 which reaches the surface of the silicon substrate 21 is suitably formed on the first interlayer insulating film 25. A first metal 27 composing the word lines WL as the first wiring of the memory cell array is formed on the first interlayer insulating film 25 by low-resistance metal such as W. A barrier metal 28 is formed on a layer above the first metal 27. The barrier metal may be formed on a layer below the first metal 27. The barrier metal can be formed by both or one of Ti and TiN. A non-ohmic element 29 such as a diode is formed above the barrier metal 28. A first electrode 30, a variable resistive element 31 and a second electrode 32 are formed in this order on the non-ohmic element 29. As a result, the barrier metal 28 to the second electrode 32 are composed as the memory cell MC. A barrier metal may be inserted into a lower portion of the first electrode 30 and an upper portion of the second electrode 32, or a barrier metal or an adhesive layer may be inserted into a lower side of the second electrode 32 and an upper side of the first electrode 30. The memory cell MC is formed into a tapered shape such that its cross section area becomes gradually narrower from the lower end to the upper end. A portion between the adjacent memory cells MC is filled with a second interlayer insulating film 34 and a third interlayer insulating film 35 (the second interlayer insulating film 34 is not shown in FIG. 8). A second metal 36, which extends to a direction perpendicular to the word lines WL and composes the bit lines BL as the second wiring, is formed on each memory cell MC in the memory cell array. A fourth interlayer insulating film 37 and a metal wiring layer 38 are formed thereon, so that a nonvolatile memory as a variable resistive memory is formed. In order to realize a multi-layered structure, the lamination from the barrier metal 28 to the upper electrode 32, and the formation of the second and third interlayer insulating films 34 and 35 between the memory cells MC are repeated for the necessary number of laminations.

[Manufacturing Method According to the First Embodiment]

A method for manufacturing the nonvolatile memory according to the embodiment shown in FIG. 8 will be described below.

An FEOL (Front End Of Line) process for forming a transistor or the like composing the necessary peripheral circuit on the silicon substrate 21 is executed, and the first interlayer insulating film 25 is deposited on the silicon substrate 21. The via 26 is also fabricated at this time.

Thereafter, the upper layer portion after the first metal 27 is formed.

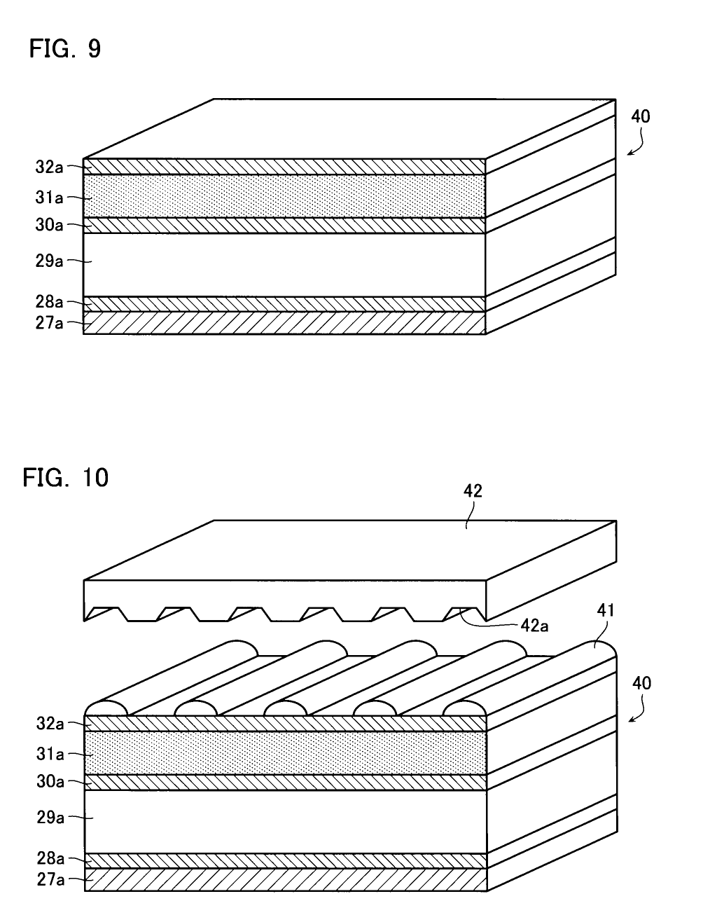

FIGS. 9 to 18 are perspective views illustrating steps of forming the upper layer portion in order of the steps.

The process for forming the upper layer portion will be described with reference to FIGS. 9 to 18.

After the first interlayer insulating film 25 and the via 26 are formed, deposition of a layer 27a to be the first metal 27 in the memory cell array, formation of a layer 28a to be the barrier metal 28, deposition of a layer 29a to be the non-ohmic element 29, deposition of a layer 30a to be the first electrode 30, deposition of a layer 31a to be the variable resistive element 31, and deposition of a layer 32a to be the second electrode 32 are executed thereon in this order. A laminate body 40 of the upper layer portion shown in FIG. 9 is formed by the above steps.

Thereafter, a nanoimprint technique is used for forming tapered grooves in this embodiment. Liquid resist 41 with low viscosity is dropped onto an upper surface of the laminated body 40, and a template 42 made of quartz is pushed against the upper surface by very weak strength. A plurality of parallel grooves 42a are formed on a lower surface of the template 42. The grooves 42a have a trapezoidal cross section in which an opening side has a wider width. The template 40 is processed by a normal method such as photolithography, but since microfabrication in L/S up to 10 nm order is enabled, a minute cross point structure can be created by using the template 40. The template 42 is pushed against the laminated body 40 so that a direction in which the grooves 42 extend becomes parallel with the word line WL. The inside of the grooves 42a is filled with the resist 41 without a gap.

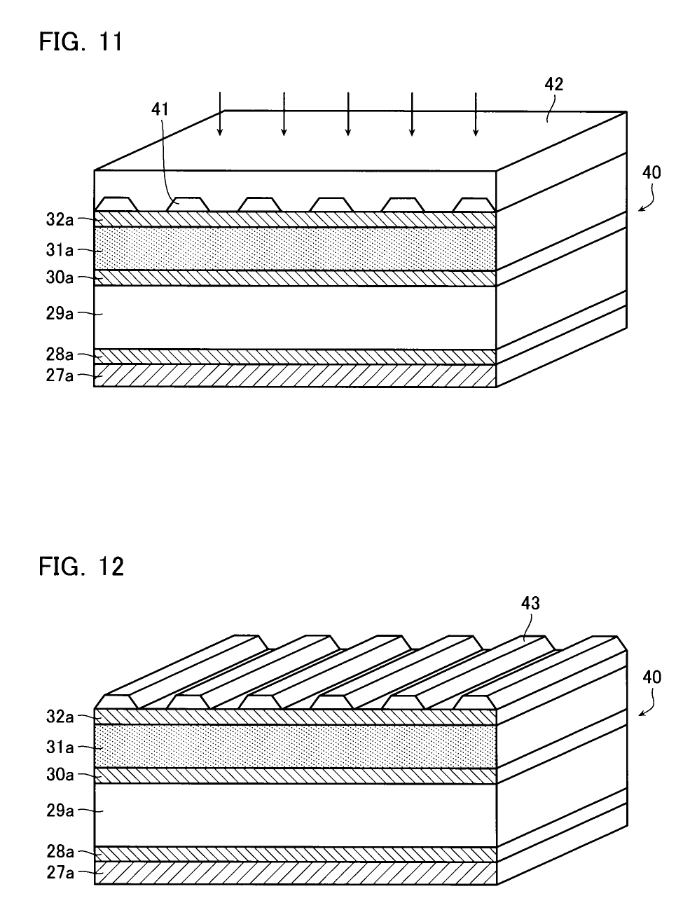

As shown in FIG. 11, an ultraviolet ray is emitted to the template 42 so that the resist 41 is exposed. As a result, cross-linkage of the resist 41 is stimulated, and the template 42 is removed. As a result, a resist pattern 43 having a trapezoidal cross section shown in FIG. 12 is formed. The step of dropping the resist 41 through the step of exposing the resist 41 are repeated by step-and-repeat, so that a resist pattern 43 is formed on the entire laminated body 40.

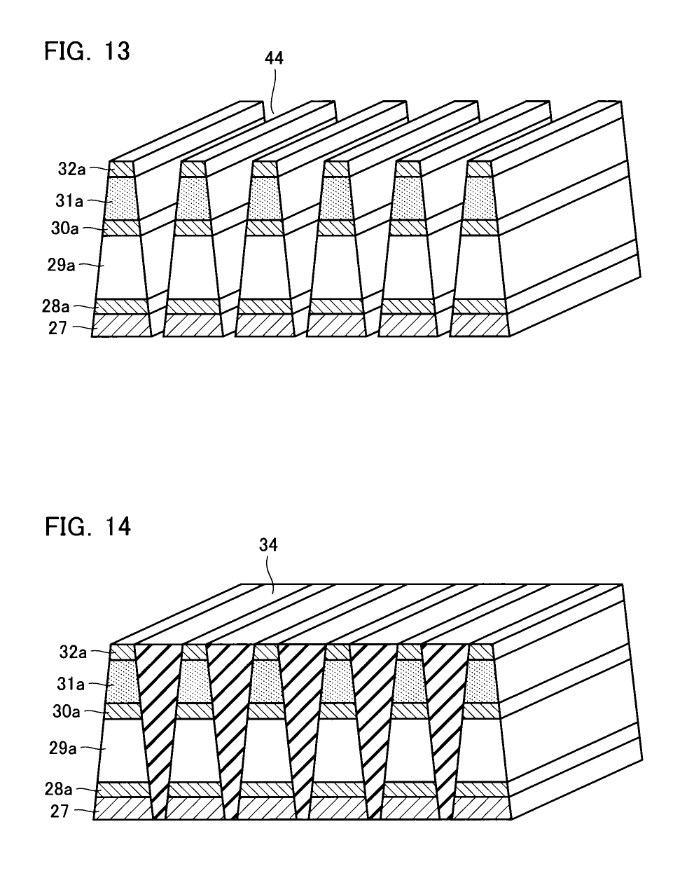

Thereafter, the formed resist pattern 43 is used as a mask to carry out first anisotropic etching, and grooves 44 are formed along the word lines WL as shown in FIG. 13 so that the laminated body 40 is divided. Since the resist pattern 43 has the trapezoidal cross section, edges on both sides of the resist pattern 43 gradually retreat to the inside according to the progress of the etching. As a result, widths of the grooves 44 are wider towards opening sides, and the laminated body 40 is etched into a tapered shape.

A second interlayer insulating film 34 is embedded into the grooves 44. A material of the second interlayer insulating film 34 may have insulating property, and suitably has low capacity and satisfactory embedding property. A flattening process is executed by CMP or the like, so that an excessive portion of the second interlayer insulating film 34 is removed and the upper electrode 32 is exposed. The cross-sectional view after the flattening process is shown in FIG. 14.

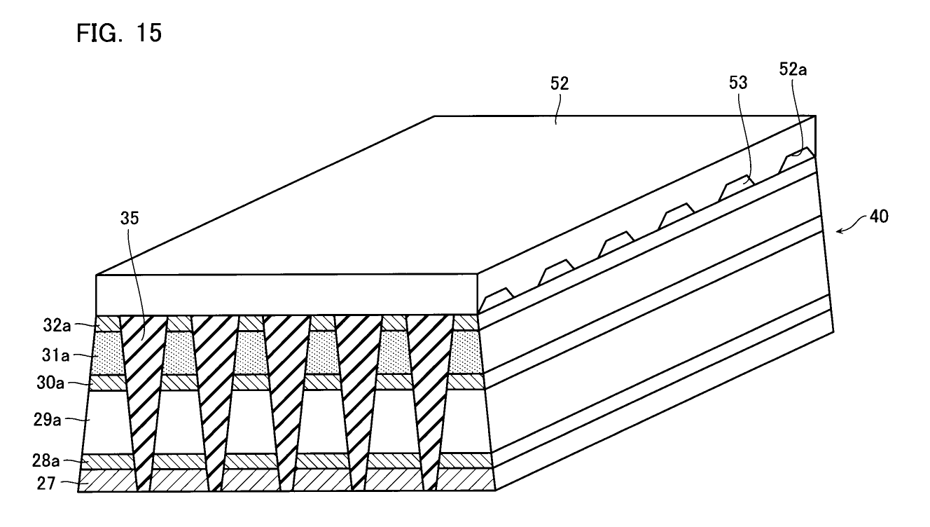

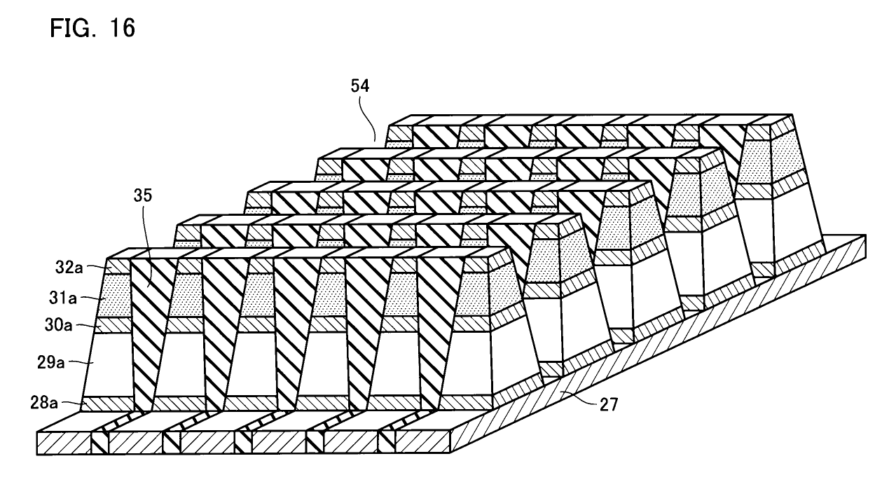

Second etching is carried out in L/S in a direction crossing the first etching. In this case, as shown in FIG. 15, a template 52 made of quartz having grooves 52a with trapezoidal cross section whose opening side is wider is used, so that a resist pattern 53 having the trapezoidal cross section is formed by the nanoimprint technique. As a result, as shown in FIG. 16, grooves 54 are formed along the bit lines BL perpendicular to the word lines WL, and simultaneously the memory cells MC, which are separated into a small pillar shape where a cross section of its upper portion is smaller than that of its lower portion, are formed.

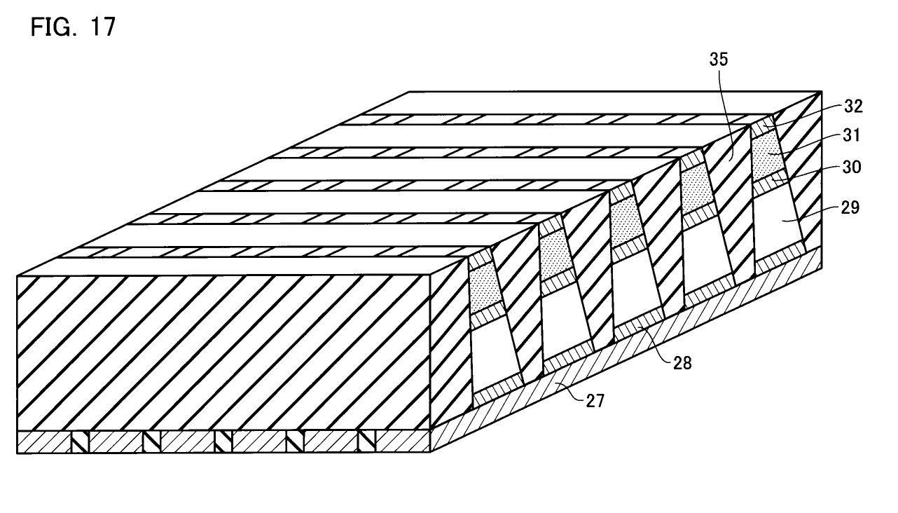

The third interlayer insulating film 35 is then embedded into the grooves 54. A material of the third interlayer insulating film 35 suitably has satisfactory insulating property, low capacity and satisfactory embedding property. Then, the flattening process is executed by CMP or the like, so that an excessive portion of the third interlayer insulating film 35 is removed and the upper electrode 32 is exposed. A cross-sectional view after the flattening process is shown in FIG. 17.

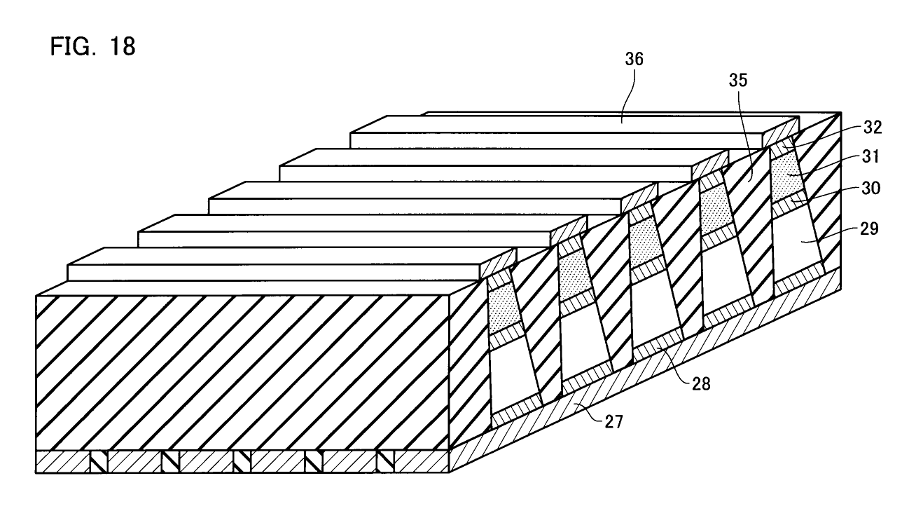

As shown in FIG. 18, after a layer made of tungsten to be the second metal 36 is laminated on the flattened portion which has been subject to CMP, it is etched to form the second metal 36.

A multi-layer cross point type memory cell array can be formed by repeating the formation of the multi-layered structure. At this time, when the step of the deposition of the barrier metal layer 28 and subsequent steps are repeated, the memory cell array where wiring is shared by the adjacent memory cell arrays on upper and lower layers can be realized. When the step of the formation of the first interlayer insulating film 25 and subsequent steps are repeated, the memory cell array, where the wiring is not shared by the memory cell arrays adjacent on the upper and lower layers, can be realized.

Thereafter, the nonvolatile semiconductor storage apparatus according to the embodiment is formed by forming the metal wiring layer 38.

As a result, the memory cells MC can be formed into the tapered shape in which their cross section area on the variable resistive element 31 side becomes smaller than that on the non-ohmic element 29 side. For this reason, the current density of the variable resistive element 31 and the current value of the non-ohmic element 29 can be heightened.

In order to form such a tapered shape, besides the above manufacturing method, etching by means of normal resist film formation, etching using a hard mask such as TEOS, SiO₂, SiN or amorphous Si may be used. In these etching methods, etching conditions are variously changed so that the memory cells MC can be formed into the tapered shape.

### Second Embodiment

FIG. 19 is a perspective view illustrating a memory cell portion of the nonvolatile semiconductor storage apparatus according to a second embodiment of the present invention. In the second embodiment, the arrangements of the non-ohmic element NO and the variable resistive element VR are upside down with respect to the arrangements in FIG. 3. Also in such a constitution, the cross section area on the variable resistive element VR side is smaller than that on the non-ohmic element NO, so that the effect of the present invention can be obtained. In this case, the memory cells MC having a reverse tapered shape may be formed under etching conditions towards overetching.

### Third Embodiment

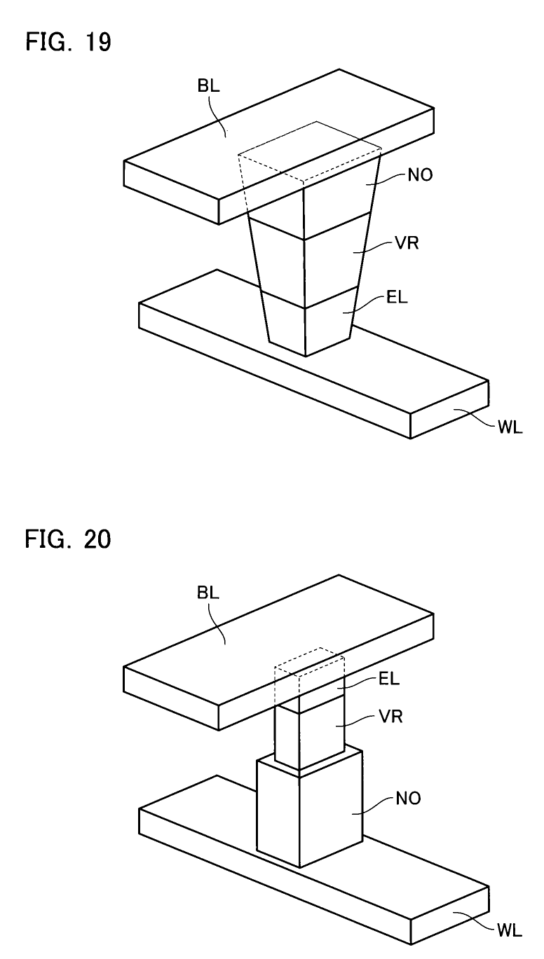

FIG. 20 is a perspective view illustrating a memory cell portion of the nonvolatile semiconductor storage apparatus according to a third embodiment of the present invention. In the third embodiment, the cross section area of the non-ohmic element NO and the cross section area of the variable resistive element VR are made to be constant, and the former area is larger than the latter area. Even with such a constitution, the effect of the present invention can be obtained.

### Another Embodiment

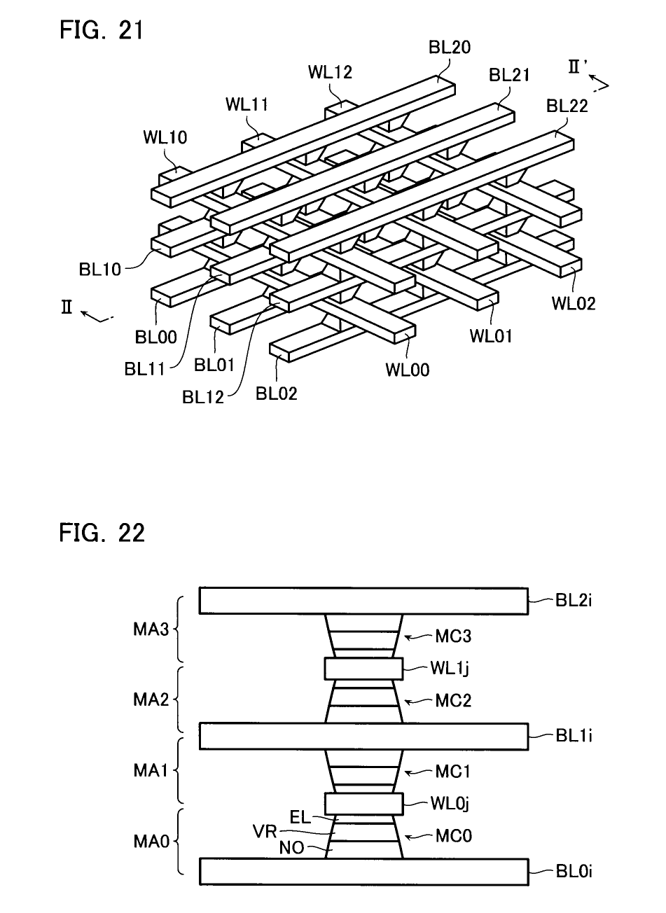

As shown in FIG. 21, a three-dimensional structure in which a plurality of memory structures are laminated can be obtained. FIG. 22 is a cross-sectional view illustrating a cross section taken along line II-II′ of FIG. 21. An example of FIG. 21 shows a memory cell array having a four-layered structure including cell array layers MA0 to MA3. A word line WL0j is shared by the upper and lower memory cells MC0 and MC1, a bit line BL1i is shared by the upper and lower memory cells MC1 and MC2, and a word line WL1j is shared by the upper and lower memory cells MC2 and MC3. Each memory cell MC is formed into the tapered shape so that its cross section area on the non-ohmic element NO side becomes larger than that on the variable resistive element VR side. Unlike repetition such as wiring/cell/wiring/cell but like wiring/cell/wiring/interlayer insulating film/wiring/cell/wiring, the interlayer insulating film may be interposed between the cell array layers.

The memory cell array 1 can be divided into MATs in some memory cell groups. The column control circuit 2 and the row control circuit 3 may be provided for each MAT, each sector or each cell array layer MA, or may be shared by them. Further, the circuits may be shared by a plurality of bit lines BL in order to reduce the area.

What is claimed is:

1. A nonvolatile semiconductor storage apparatus comprising:
a plurality of first wirings;
a plurality of second wirings which cross the plurality of first wirings; and
a memory cell which is connected between both the wirings at an intersection of the first and second wirings, and includes a variable resistive element operative to store information according to a change in resistance,
wherein the memory cell is formed so that a cross section area of the variable resistive element becomes smaller than a cross section area of the other portion.

2. The nonvolatile semiconductor storage apparatus according to claim 1, wherein
the memory cell includes a non-ohmic element which is connected to the variable resistive element in series, and
the non-ohmic element is formed so that its cross section area becomes larger than the cross section area of the variable resistive element.

3. The nonvolatile semiconductor storage apparatus according to claim 1, wherein
the memory cell is formed so that its cross section area is gradually smaller from the first wiring side to the second wiring side, and
the variable resistive element is arranged on the second wiring side.

4. The nonvolatile semiconductor storage apparatus according to claim 2, wherein
the memory cell is formed so that its cross section area is gradually smaller from the first wiring side to the second wiring side, and
the variable resistive element is arranged on the second wiring side.

5. The nonvolatile semiconductor storage apparatus according to claim 4, wherein the non-ohmic element is arranged on the side closer to the first wiring than to the variable resistive element.

6. The nonvolatile semiconductor storage apparatus according to claim 1, wherein
a width in the second wiring direction at a connecting terminal of the memory cell on the first wiring side is larger than a width in the second wiring direction at a connecting terminal of the memory cell on the second wiring side and is equal to a width of the first wiring, and
a width in the first wiring direction at the connecting terminal of the memory cell on the first wiring side is larger than a width in the first wiring direction at the connecting terminal of the memory cell on the second wiring side and a width of the second wiring.

7. The nonvolatile semiconductor storage apparatus according to claim 2, wherein
the cross section areas of the non-ohmic element and the variable resistive element are constant, and
the non-ohmic element has a larger cross section area than that of the variable resistive element.

8. The nonvolatile semiconductor storage apparatus according to claim 1, wherein the variable resistive element is composed of a composite compound including cations as transition elements, and changes the resistance by means of transfer of the cations.

9. The nonvolatile semiconductor storage apparatus according to claim 2, wherein the non-ohmic element is a diode.

10. A nonvolatile semiconductor storage apparatus comprising:
a memory cell array including plural stacked cell array layers, each cell array layer comprising a plurality of first wirings, a plurality of second wirings which cross the plurality of first wirings, and memory cells which are connected at intersections of the first and second wirings, and each memory cell includes a variable resistive element operative to store information according to a change in resistance,
wherein the memory cell is formed so that a cross section area of the variable resistive element becomes smaller than a cross section area of the other portion.

11. The nonvolatile semiconductor storage apparatus according to claim 10, wherein
the memory cell includes a non-ohmic element which is connected to the variable resistive element in series, and
the non-ohmic element is formed so that its cross section area becomes larger than that of the variable resistive element.

12. The nonvolatile semiconductor storage apparatus according to claim 10, wherein
the memory cell is formed so that its cross section area is gradually smaller from the first wiring side to the second wiring side, and
the variable resistive element is arranged on the second wiring side.

13. The nonvolatile semiconductor storage apparatus according to claim 11, wherein
the memory cell is formed so that its cross section area is gradually smaller from the first wiring side to a second wiring side, and
the variable resistive element is arranged on the second wiring side.

14. The nonvolatile semiconductor storage apparatus according to claim 10, wherein
a width in a second wiring direction at a connecting terminal of the memory cell on the first wiring side is larger than a width in the second wiring direction at a connecting terminal of the memory cell on the second wiring side and is equal to a width of the first wiring, and
a width in the first wiring direction at the connecting terminal of the memory cell on the first wiring side is larger than a width in the first wiring direction at the connecting terminal of the memory cell on the second wiring side and a width of the second wiring.

15. The nonvolatile semiconductor storage apparatus according to claim 11, wherein
the cross section areas of the non-ohmic element and the variable resistive element are constant, and
the non-ohmic element has a cross section area larger than that of the variable resistive element.

16. The nonvolatile semiconductor storage apparatus according to claim 10, wherein at least one of the first and second wirings is shared by the memory cells of the different cell array layers.

17. The nonvolatile semiconductor storage apparatus according to claim 10, wherein an interlayer insulating film is interposed between the two cell array layers adjacent in a laminated direction.

18. A method of manufacturing a nonvolatile semiconductor storage apparatus, comprising:
forming, on a semiconductor substrate, a laminated body in which at least an interlayer insulating film, a layer for forming a first wiring, a layer for forming a non-ohmic element and a layer for forming a variable resistive element are sequentially laminated;
forming a plurality of first grooves on the laminated body, the first grooves extending in a direction where the first wirings are formed, their opening side being wider than their bottom surface side, their depth reaching a lower surface of the layer for forming the first wirings,
embedding a first insulating film into the first grooves;
forming a plurality of second grooves on the laminated body into which the first insulating film is embedded, the second grooves extending in a direction where the second wirings crossing the first wirings are formed, their opening side being wider than their bottom surface side, their depth reaching an upper surface of the layer for forming the first wirings;
embedding a second insulating film into the second grooves; and
forming the second wirings on the laminated body into which the second insulating film is embedded.

19. The method of manufacturing a nonvolatile semiconductor storage apparatus according to claim 18, wherein
when the first grooves and the second grooves are formed, a resist is formed on an upper surface of the laminated body by using a nanoimprint technique so that a side wall has a tapered shape in which its lower surface is wider than an upper surface, and
the resist is used as a mask to etch the laminated body.

20. The method of manufacturing a nonvolatile semiconductor storage apparatus according to claim 19, wherein
when the resist is formed, a template formed with a plurality of parallel grooves having a trapezoidal cross section whose opening side is wider is pushed against the liquid resist with low viscosity, and the grooves on the lower surface of the template are filled with the resist without a gap, and
after an ultraviolet ray is emitted to the template and the resist is exposed, the template is removed from the resist.
